(19) United States
(12) Patent Application Publication
(10) Pub. No.: US 2025/0372506 A1
(43) Pub. Date: Dec. 4, 2025

(54) ISOLATION CIRCUITRY ON SEMICONDUCTOR DIE

(71) Applicant: TEXAS INSTRUMENTS INCORPORATED, Dallas, TX (US)

(72) Inventors: Giacomo Calabrese, Freising (DE); Nicola Bertoni, Freising (DE); Michael Lueders, Freising (DE); Stefan Herzer, Marzling (DE)

(21) Appl. No.: 18/676,314

(22) Filed: May 28, 2024

(51) Int. Cl. H01L 23/522; H01L 23/00; H01L 23/498; H01L 23/532

(52) U.S. Cl. CPC H01L 23/5226; H01L 23/49861; H01L 23/53295; H01L 24/16; H01L 24/05; H01L 24/48; H01L 24/73; H01L 2224/04042; H01L 2224/16145; H01L 2224/48157; H01L 2224/73207

(57) ABSTRACT

A packaged integrated circuit (IC) including a semiconductor die having a metallization layer, the metallization layer including first metal interconnects in a first insulation material. The IC includes a first substrate on the metallization layer, the first substrate including second metal interconnects in a second insulation material different from the first insulation material, at least one of the second metal interconnects being electrically coupled to at least one of the first metal interconnects. The IC further includes a second substrate on the first substrate, the second substrate including an isolation circuit and third metal interconnects in a third insulation material different from the first insulation material, the isolation circuit being electrically coupled to the at least one of the first metal interconnects via the at least one of the second metal interconnects and at least one of the third metal interconnects.

### BACKGROUND

Isolation is often desirable for interconnecting electrical systems to exchange data or power between the systems. For example, two systems may be powered by different supply sources that do not share a common ground connection. The two systems may be electrically isolated to prevent current and voltages in one system from negatively impacting the other system, for instance by damaging or interfering with the operation of one or more components of the other system. Creating a galvanic isolation barrier for high voltage directly on an active silicon die back-end is challenging.

### SUMMARY

Described is a packaged integrated circuit (IC) including: a semiconductor die having a metallization layer, the metallization layer including first metal interconnects in a first insulation material. In at least one example, the packaged IC comprises a first substrate on the metallization layer, the first substrate including second metal interconnects in a second insulation material different from the first insulation material, at least one of the second metal interconnects being electrically coupled to at least one of the first metal interconnects. In at least one example, the packaged IC comprises a second substrate on the first substrate, the second substrate including an isolation circuit and third metal interconnects in a third insulation material different from the first insulation material. In at least one example, the isolation circuit is electrically coupled to at least one of the first metal interconnects via the at least one of the second metal interconnects and at least one of the third metal interconnects.

In at least one example, a packaged IC includes a semiconductor die having a metallization layer, the metallization layer including first metal interconnects in a dielectric material. In at least one example, the packaged IC comprises a first layer on the metallization layer, the first layer including second metal interconnects in a first build-up material. In at least one example, at least some of the second metal interconnects are electrically coupled to at least some of the first metal interconnects. In at least one example, the packaged IC comprises a second layer on the first layer, the second layer including third metal interconnects in a second build-up material. In at least one example, at least a first subset of the third metal interconnects is electrically coupled to the at least some of the second metal interconnects, and at least a second subset of the third metal interconnects are exposed by the second layer.

In at least one example, a method is provided, which comprises forming a first substrate on a metallization layer of a semiconductor die. In at least one example, the metallization layer includes first metal interconnects in a first insulation material. In at least one example, the first substrate includes second metal interconnects in a second insulation material different from the first insulation material. In at least one example, at least one of the second metal interconnects is electrically coupled to at least one of the first metal interconnects. In at least one example, the method comprises forming a second substrate on the first substrate. In at least one example, the second substrate includes an isolation circuit and third metal interconnects in a third insulation material different from the first insulation material. In at least one example, the isolation circuit is electrically coupled to at least one of the first metal interconnects via at least one of the second metal interconnects and at least one of the third metal interconnects.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1A is a schematic depicting an example packaged integrated circuit (IC) having an isolation circuit comprising a power transformer, the isolation circuit over a semiconductor die, in accordance with at least one example.

FIG. 1B is a schematic depicting an example packaged IC having an isolation circuit comprising a power transformer and one or more data transformers, the isolation circuit over the semiconductor die, in accordance with at least one example.

FIG. 2 is a schematic depicting a cross-sectional view of a stack of layers of the packaged IC comprising an isolation circuit on a semiconductor die, in accordance with at least one example.

FIG. 3A is a schematic depicting a cross-sectional view of a stack of layers of the packaged IC comprising a flip-chip semiconductor die on top of the isolation circuit, which is on a semiconductor die, in accordance with at least one example.

FIG. 3B is a schematic depicting a top view of the schematic of FIG. 3A, in accordance with at least one example.

FIG. 4A is a schematic depicting a cross-sectional view of a stack of layers of the packaged IC comprising the isolation circuit, which is on a second semiconductor die and, where a first semiconductor die is adjacent to the second semiconductor die, in accordance with at least one example.

FIG. 4B is a schematic depicting a top view of the schematic of FIG. 4A, in accordance with at least one example.

FIGS. 5A-C illustrate schematics of top views of the schematic of FIG. 3A showing a single channel power isolation transformer, a single channel data isolation transformer, and multi-channel data isolation transformers, respectively, in accordance with some examples.

FIGS. 6A-B illustrate schematics of packaged ICs having functional isolation and reinforced isolation, respectively, in accordance with some examples.

FIG. 7 is a flowchart of a method of forming the packaged IC, in accordance with at least one example.

### DETAILED DESCRIPTION OF EXAMPLE EMBODIMENTS

Described herein is a packaged integrated circuit (IC) that comprises two semiconductor dies that are coupled to an isolation circuit (e.g., an isolation barrier), which is integrated within a substrate. In at least one example, the two semiconductor dies include a first semiconductor die and a second semiconductor die. One of the first or second semiconductor die forms a base die such that the substrate including the isolation circuit is on the base die. In at least one example, the base die (e.g., the second semiconductor die) includes a back end-of-line (BEOL) layer with first metal interconnects embedded in a dielectric material. In at least one example, the BEOL layer is on a semiconductor substrate of the second semiconductor die.

In at least one example, the packaged IC includes multiple substrates on the BEOL layer, with a first substrate including second metal interconnects including metal posts surrounded by a first insulation material, and a second substrate including third metal interconnects surrounded by a second insulation material. In at least some examples, the second substrate can include a routable lead frame (RLF). In at least one example, the first substrate includes one of a wafer-level build-up film having a first Ajinomoto build-up film (ABF), a solder mask, an epoxy material (e.g., polyimide), acrylonitrile butadiene styrene (ABS), acrylonitrile styrene acrylate (ASA), or epoxy resin as the first insulation material. In at least one example, the second substrate includes a second ABF as the second insulation material.

In at least one example, the first substrate can include multiple layers of metal interconnects including the second metal interconnects. In at least one example, the second substrate can include multiple layers of metal interconnects including the third metal interconnects. In at least one example, the isolation circuit comprises a transformer formed with the second and third metal interconnects separated by a critical separation distance based on target isolation characteristics of the isolation circuit. As discussed herein, the isolation circuit may also include capacitors implemented in the second and third metal interconnects as capacitor plates, and the first and second insulation materials between them as the dielectric of the capacitor.

In at least one example, the first semiconductor die is a flip-chip die, which is coupled to third metal interconnects via metal posts (e.g., copper posts). The third metal interconnects may include a primary winding (e.g., top winding) in the second ABF. In at least one example, the first semiconductor die is on top of the second ABF. In at least one example, the flip-chip configuration of the first semiconductor die allows connection with the transformer(s) below it with reduced interconnection routing and parasitic. In at least one example, a region between surfaces of the second ABF and the first semiconductor die provides forms an additional isolation barrier, which comprises part of a mold compound that surrounds the stack of metal posts.

In at least one example, the second semiconductor die includes a first power circuit and the second semiconductor die includes a second power circuit. In at least one example, the first semiconductor die is coupled to the second semiconductor die via a power transformer formed in at least one of the second and third metal interconnects, where the transformer is part of the isolation circuit. In at least one example, the power transformer comprises two windings in two different metal interconnect layers.

In at least one example, the second semiconductor die (e.g., base die) has at least one edge or dimension longer than an edge or dimension of the first semiconductor die (e.g., flip-chip die), which allows the first semiconductor die to be mounted on the second semiconductor die. In at least one example, bond wires are coupled to one or more third metal interconnects surrounded by the second ABF and to one or more bond pads on the periphery of the packaged IC. In at least one example, the bond pads are coupled to respective pins of the packaged IC that allow the packaged IC to connect with other devices on a printed circuit board (PCB).

In at least one example, the first semiconductor die and the second semiconductor die include data circuits that are coupled via a data transformer (or a set of data transformers) formed in at least one of the second and third metal interconnects, where the data transformer is also part of the isolation circuit. The data circuits provide bidirectional signaling, in accordance with at least one example. In at least one example, the data transformer or the set of data transformers are positioned within openings of windings of the power transformer and within the footprint of the power transformers. In at least one example, the data circuits are used for sending and receiving signals via one or more data channels between the first and second power semiconductor dies to realize a DC-DC converter. In at least one example, the data circuits can be used for other functions such as telemetry, data signaling, buffering of analog input signals for an analog-to-digital converter, buffering of digital input signals for a digital-to-analog converter, etc. In at least one example, the data transformer can be multiplexed between sending internal data (e.g., feedback data from the secondary side back to the primary side within the packaged IC) and external data (e.g., external to the packaged IC). In at least one example, an additional semiconductor die is positioned adjacent to the second semiconductor die (e.g., base die), where the additional semiconductor die receives power from the first or second power semiconductor dies and sends and receives data to and from the data circuit of the first or second semiconductor dies. The additional semiconductor die can be any application specific semiconductor die or a general microcontroller.

In at least one example, the first semiconductor die is laterally adjacent to the second semiconductor die. Such arrangements can reduce the constraints on the size of the first semiconductor die to the size of the second semiconductor die. In at least one example, the third metal interconnects of the second substrate are coupled to the first semiconductor die via bond wires.

By integrating the first and second semiconductor dies for power regulation and data transfer with the isolation circuit, which is integrated in the first and second substrates, the overall size of the packaged IC can be reduced. The flip-chip assembly for the first semiconductor die allows for tighter parameter control which reduces the size or area of the packaged IC, which can result in shorter and/or fewer interconnect routing, closer connections, smaller parasitic capacitances, resistances, and/or inductances, etc. The flip-chip assembly for the first semiconductor die can overlap the power and/or data transformers, which can reduce parasitic capacitances, resistances, and/or inductances involved in connecting the transformers to the first semiconductor die. In at least one example, since the first and second semiconductor dies are stacked with isolation circuit between the first and second semiconductor dies, the x-y footprint of the packaged IC reduces. Routing over the second substrate (e.g., using wire bonding) can be eliminated or at least reduced as most signal and power routings can be in the first and second substrates. The reduced parasitic capacitances, resistances, and/or inductances involved in connecting the transformers of the isolation circuit with respect to a bonded assembly, allow tailoring of the power and data channels down to the application needs and achieve higher power transfer efficiency.

Reduced parasitic capacitances, resistances, and/or inductances increase transformer coupling that also translates to higher power transfer efficiency. In at least one example, the isolation barrier between the top winding of the power transformer and the first semiconductor die allows for enough clearance and isolation between the top winding and the first semiconductor die that two very different power domains can be used for the first and second semiconductor dies. Because of the reduced parasitic capacitances, resistances, and/or inductances, ringing in the power supply can also be reduced, which can improve reliability and improve noise immunity and bandwidth of data transmission.

Moreover, by placing the transformers of the isolation circuit in the first and second substrates, which can be much thicker than the transformer windings, the vertical separation between the transformer windings and the first semiconductor die can be increased, at least compared with the case where the transformer windings (or other isolation circuit) are formed in the metallization layer (e.g., BEOL layer) of the first semiconductor die. Such arrangements can reduce the parasitic capacitance between the transformer windings and the first semiconductor die, which can provide connection to ground. The reduced parasitic capacitance can also improve the quality factor (QF) of the transformer (an inductive channel). The improvement in QF may also result from lower induced eddy currents in the substrate and thus lower loss. For isolation circuit with capacitive channels, the reduced parasitic capacitance to substrate allows for lower energy to drive a signal across the isolation circuit or channel.

The increased vertical separation between the first semiconductor die and the top winding can also reduce the eddy current in the first semiconductor die caused by the magnetic field generated by the transformer, which can reduce loss and further improve power transfer efficiency. The transformer can also provide improved common mode transient immunity due to improved matching for differential signals.

The flexibility in the routing capability of the package substrate also improves the connectivity and signal integrity. The packaged IC of some examples integrate power and bidirectional data communication with minimized/reduced crosstalk, so that they operate independently, which makes the use of the isolated co-packaged device more flexible. In at least one example, the first and second substrates comprising metal layers improve efficiency for power transformers using thicker metal (e.g., copper) traces. In at least one example, when the first semiconductor die is over the second substrate, the transformers in the first and second substrates can be distanced from the first semiconductor die, which can reduce the Eddy current loss in the semiconductor substrate of the first semiconductor die induced by the transformers. Accordingly, compared with transformers that are integrated in the silicon metallization layers, transformers in the first and second substrates can have higher QFs. Embedding the data transformers in the first and second substrates also allows for high frequency signal communication between data integrated circuits. Routing signal and power through the first and second substrates reduces interconnect congestion on top of the second substrate, which allows for smaller packaged integrated circuit as semiconductor dies in the packaged integrated circuit are placed closer to one another.

In the drawings, like reference numerals refer to like elements throughout, and the various features are not necessarily drawn to scale. Here, the same reference numbers or other reference designators are used in the drawings to designate the same or similar (either by function and/or structure) features.

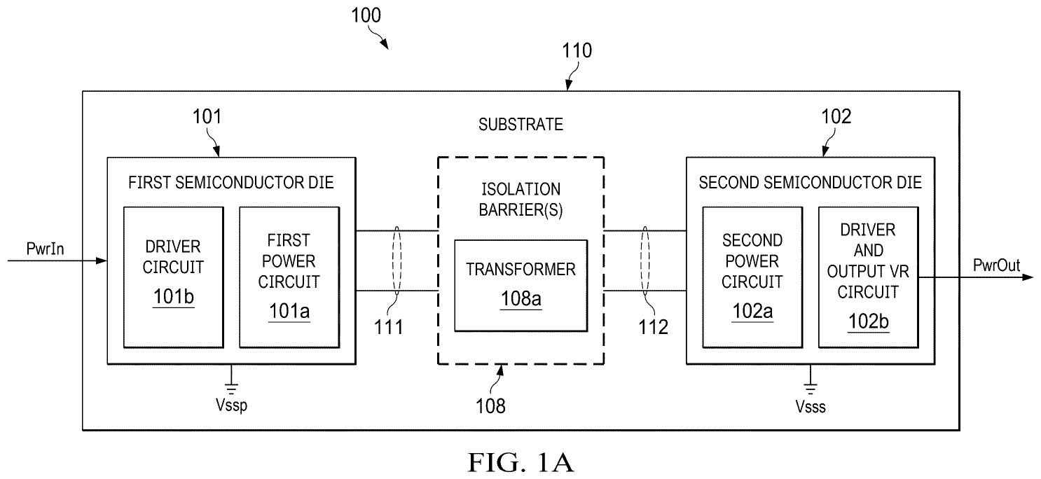

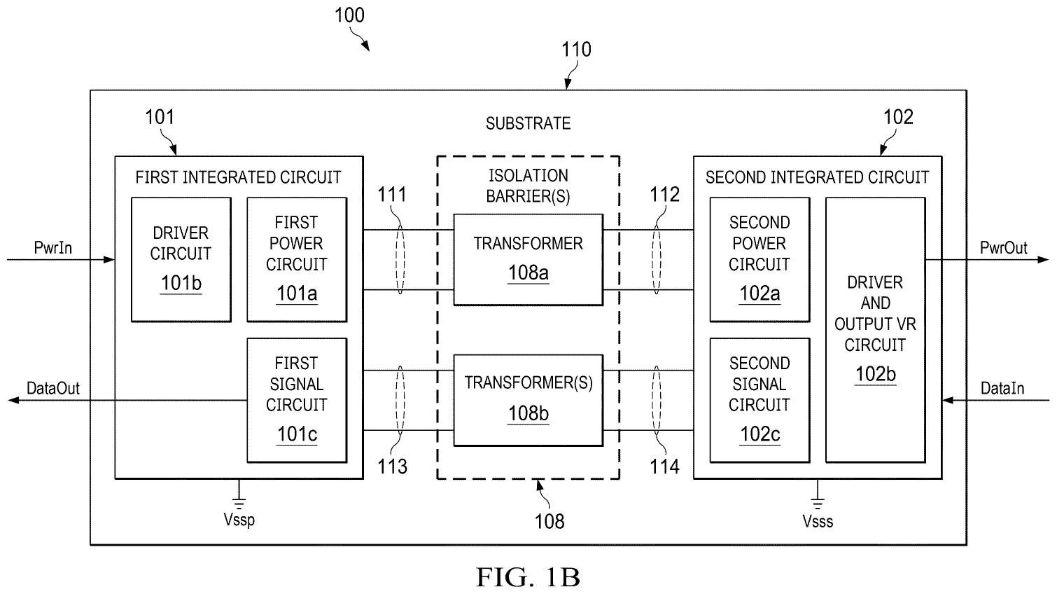

FIG. 1A is a schematic depicting an example packaged IC 100 having an isolation circuit comprising a power transformer, the isolation circuit over a semiconductor die (e.g., a base die), in accordance with at least one example. In at least one example, packaged IC 100 includes a first semiconductor die 101, a second semiconductor die 102, an isolation circuit 108, and a package substrate 110.

In at least one example, second semiconductor die 102 (base die) is mounted to package substrate 110, which can include a lead frame, one or more die pads, etc., and support second semiconductor die 102 as a circuit support structure. In at least one example, first and second semiconductor dies 101 and 102 are stacked such that isolation circuit 108 is between first and second semiconductor dies 101 and 102.

In at least one example, first and second semiconductor dies 101 and 102 are mounted to package substrate 110, which can support first and second semiconductor dies 101 and 102 as a circuit support structure. In at least one example, first and second semiconductor dies 101 and 102 are laterally arranged next to one another such that isolation circuit 108 on a BEOL layer of second semiconductor die 102 and coupled to first semiconductor die 101 via bond wires or other interconnection means. The BEOL layer of second semiconductor die 102 includes first metal interconnects that provide connection between isolation circuit 108 and second semiconductor die 102 (base die).

In at least one example, isolation circuit 108 is integrated, formed, or embedded into layers (not shown) of a substrate, as indicated by dashed lines. In at least one example, the substrate includes a first substrate with second metal interconnects including metal posts and a second substrate with third metal interconnects formed by routable lead frame (RLF) technology. In at least one example, the first substrate includes one of a wafer-level build-up film having a first Ajinomoto build-up film (ABF), a solder mask, or an epoxy material (e.g., polyimide). In at least one example, the second substrate includes RLF. In at least one example, the second substrate includes a second ABF.

In at least one example, second semiconductor die 102 includes a back end-of-line (BEOL) layer with a substate material (e.g., silicon dioxide) and first metal interconnects embedded in the substrate material. In at least one example, the BEOL layer is on a semiconductor substrate of second semiconductor die 102. In at least one example, the second substrate, which includes the wafer-level build-up is on the BEOL layer forming a stack of layers.

In at least one example, first semiconductor die 101 is a flip-chip die, which is coupled to third metal interconnects, forming a primary winding (e.g., top winding) in the second ABF, via metal posts (e.g., copper posts). In at least one example, first semiconductor die 101 is on top of the second ABF.

In at least one example, first semiconductor die 101 is not on top of the second ABF but laterally adjacent to second semiconductor die 102. In at least one example, the third metal interconnects of the second substrate are coupled to first semiconductor die 101 via bond wires. In at least one example, when first semiconductor die 101 (lateral die) is adjacent to second semiconductor die 102 (base die), there are no constraints on the size of the first semiconductor die to the size of the second semiconductor die.

In at least one example, package substrate 110 includes contact pads (not shown) to allow first and second semiconductor dies 101 and 102 to connect with external devices. In at least one example, packaged IC 100 includes metallic interconnects 111 and 112 (four shown) to allow interconnectivity between first and second semiconductor dies 101 and 102 and isolation circuit 108. Each interconnect 111 and 112 may represent power and/or data channels with one or more electrical traces and/or vias.

In at least one example, isolation circuit 108 (and other isolation circuit examples in accordance with this description) may provide a galvanic isolation barrier between two different power domains. In at least one example, packaged IC 100 can include a direct current (DC)-to-DC converter having a transformer as isolation circuit 108. In at least one example, the DC-to-DC converter comprises circuits in first semiconductor die 101 and second semiconductor die 102 coupled via transformer 108a of isolation circuit 108. Accordingly, first semiconductor die 101 may include circuits, such as a first power circuit 101a (e.g., half-bridge inverter or a full-bridge inverter) and a driver circuit 101b, for providing a voltage and a current from other circuit to a primary winding of transformer 108a. In at least one example, the voltage and the current are provided from a power supply for a printed circuit board (PCB) on which package substrate 110 is mounted. The PCB may be used to power a device such as a motor or a computing device.

In at least one example, second semiconductor die 102 may include a second power circuit 102a (a half-bridge rectifier or a full-bridge rectifier) and driver and regulation circuit 102b for receiving a voltage and a current from a secondary winding of transformer 108a and providing one or more regulated output voltages and/or currents for use by a load on the PCB. The load may be an application-specific integrated circuit (ASIC), a field-programmable gate array (FPGA), a microcontroller, a processor, etc. In at least one example, first and second semiconductor dies 101 and/or 102 may represent controller circuit, current and voltage sensors, gate drivers for insulated-gate bipolar transistors, gate drivers for field effect transistors (FETs), etc.

In at least one example, transformer 108a comprises a primary winding and a secondary winding. Examples of topologies for transformer 108a include a figure-of-B shaped transformer, a figure-of-8 shaped transformer, or any other suitable topology. In at least one example, the primary winding is on a top metal layer of second substrate having an isolation barrier between the primary winding and surface of first semiconductor die 101.

In at least one example, the isolation barrier is a first isolation barrier and includes part of the second substrate and part of a mold compound surrounding first and second semiconductor dies 101 and 102, respectively. In at least one example the first isolation barrier provides isolation between first semiconductor die 101 and transformer 108a so that different power supply domains can be used for first and second semiconductor dies 101 and 102 while allowing first semiconductor die 101 to overlap transformer 108a. In at least one example, a second isolation barrier is formed between the primary winding and the secondary winding of transformer 108a and includes the first and second substrates. In at least one example, the second isolation barrier allows the metal layer for the primary winding to now have smaller gaps (e.g., reduced clearance specification).

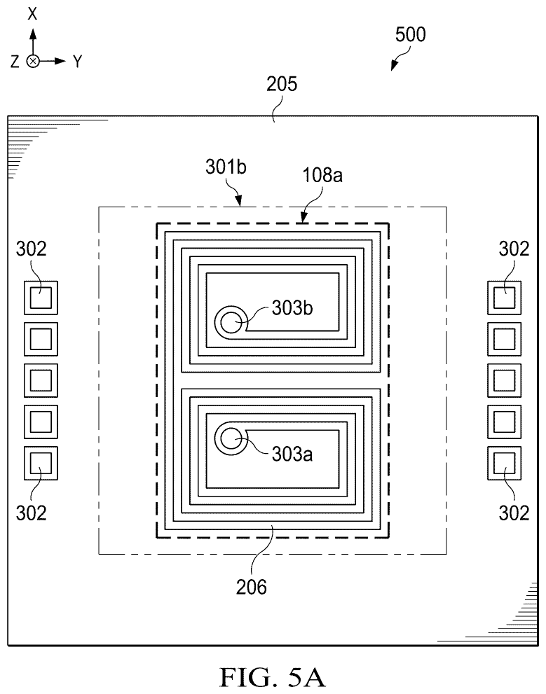

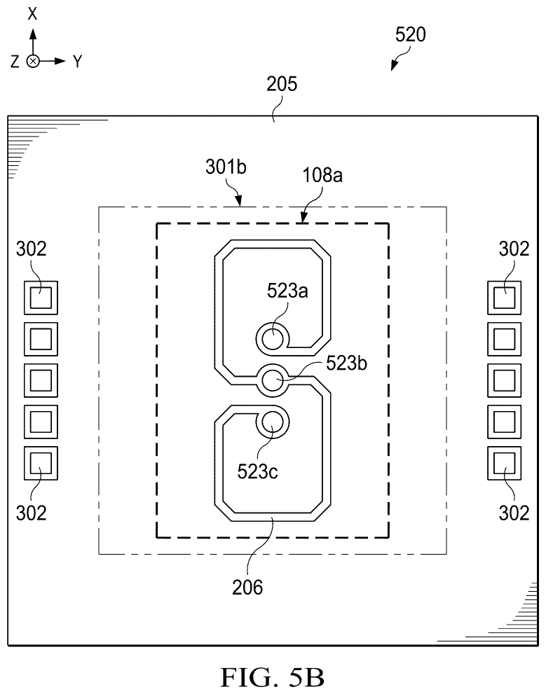

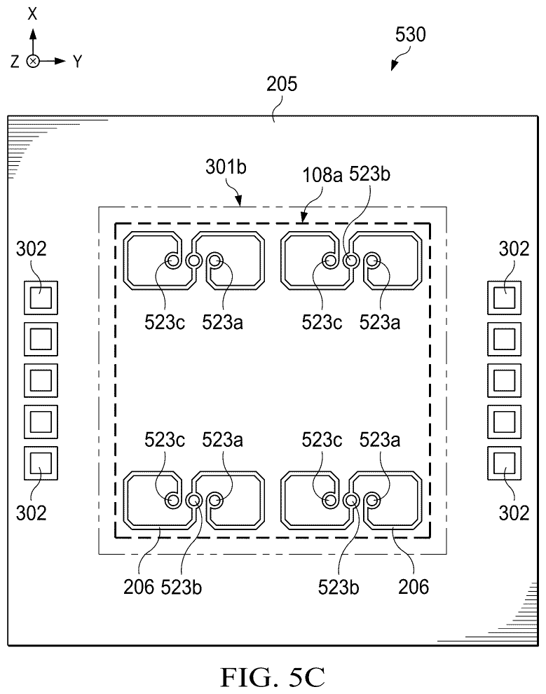

In at least one example, isolation circuit 108 may include one or more isolation circuits as shown in FIGS. 5A-C.

FIG. 1B is a schematic depicting another example of packaged IC 100 having an isolation circuit comprising a power transformer and one or more data transformers, the isolation circuit over the semiconductor die, in accordance with at least one example.

In at least one example, first semiconductor die 101 and second semiconductor die 102 include first and second signals circuits 101c and 102c, respectively, that are coupled via a data transformer 108b (or a set of data transformers), which is also part of the isolation circuit. In at least one example, first and second signals circuits 101c and 102c provide bidirectional signaling via interconnects 113 and 114, respectively. In at least one example, interconnects 113 and 114 form one or more data channels and include full duplex communication buses. In at least one example, data transformer 108b (or the set of data transformers) are positioned within openings of the windings of power transformer 108a and within a footprint of power transformer 108a. In at least one example, first semiconductor die 101 is a flip-chip die that allows connection with power transformer 108a and data transformer 108b below it with reduced interconnection.

In at least one example, first and second signals circuits 101c and 102c are used for sending and receiving signals between the first and second power semiconductor dies 101 and 102 to realize a DC-DC converter. In at least one example, first and second signals circuits 101c and 102c can be used for other functions such as telemetry, data signaling, buffering of analog input signals for an analog-to-digital converter, buffering of digital input signals for a digital-to-analog converter, etc. In at least one example, data transformer 108b can be multiplexed between sending internal data (e.g., feedback data from a secondary side back to a primary side within packaged IC 100) and external data (e.g., external to packaged IC 100).

While various examples are illustrated with second semiconductor die 102 being a base die under isolation circuit 108, and first semiconductor die 101 to be a flip-chip die or a laterally placed die, the roles of first and second semiconductor dies 101 and 102 can be reversed. For example, first semiconductor die 101 may be the base die under isolation circuit 108 while the second semiconductor die 102 can be the flip-chip die or the laterally placed die.

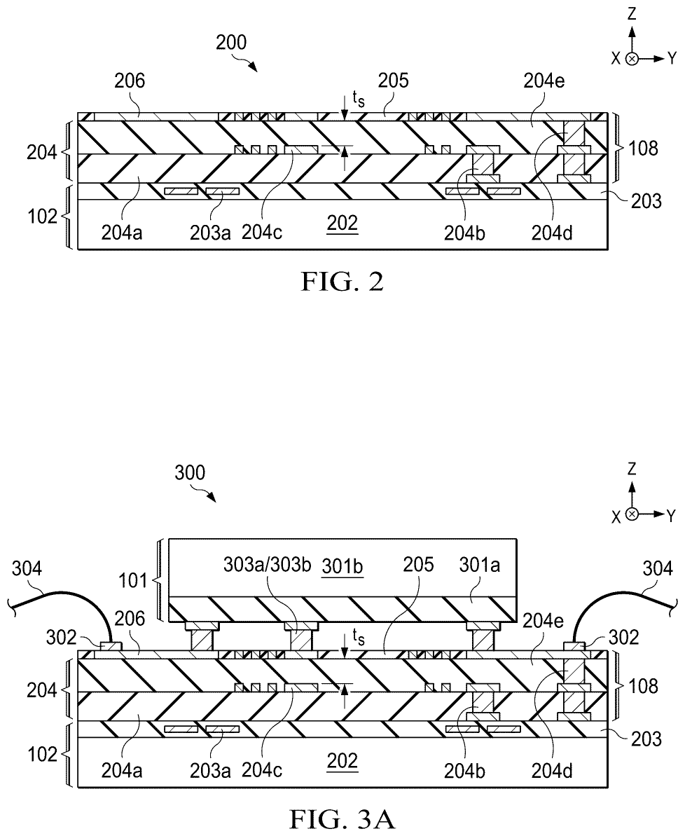

FIG. 2 is a schematic depicting a cross-sectional view of a stack of layers 200 comprising an isolation circuit on a semiconductor die, in accordance with at least one example. In at least one example, stack of layers includes second semiconductor die 102, first substrate 204, and second substrate 205. In at least one example, second semiconductor die 102 includes substrate 202 for active and/or passive devices, metal layers to interconnect various devices, and a BEOL layer having first insulation material 203. In at least one example, first insulation material 203 includes first metal interconnects 203a. In at least one example, first insulation material 203 comprises silicon dioxide (SiO₂).

A metal layer in examples described herein can include contact pads, vias, electrical traces, a thermal/ground pad, and circuit elements of an isolation circuit. Metal layers may be positioned in substantially parallel planes to one another and are substantially planar within allowable tolerances as defined by the technology used to make the package substrate. Any suitable metal may be used to form the metal layers, such as copper, aluminum, tungsten, cobalt, and gold.

In at least one example, isolation circuit 108 includes a first substrate 204 (e.g., including insulating material 204a) with second metal interconnects 204b, 204c, and 204d in a second insulation material 204e different from first insulation material 203. In at least one example, insulating material 204a is the same as second insulation material 204e. In at least one example, insulating material 204a is of a different grade than second insulation material 204e to optimize or strengthen mechanical properties for warpage. In at least one example, insulating material 204a is a different material than second insulation material 204e where insulating material 204a has a lower or similar dielectric constant. Here, second metal interconnects 204b and 204d are metal posts for connecting metals from different metal layers. In at least one example, at least one of second metal interconnects 204b, 204c, and 204d is electrically coupled to at least one of first metal interconnects 203a. In at least one example, first substrate 204 includes one of a wafer-level build-up film having a first Ajinomoto build-up film (ABF), a solder mask, or an epoxy material (e.g., polyimide). In at least one example, first substrate 204 can include multiple layers of metal interconnects including second metal interconnects 204c.

A build-up film as first substrate 204 may have multiple conductor layers in dielectric material(s) such as insulating material 204a and insulating material 204e. These multiple conductor layers include trace level conductors and connection level conductors such as second metal interconnects 204b, 204c, and 204d extending through the dielectric material between the trace level conductors. In at least one example, first substrate 204 is formed over a semiconductor wafer including multiple dies, such as second semiconductor die 102, in an additive manufacturing process. In at least one example, the semiconductor wafer is placed with a device side surface facing away from a wafer support, such as a wafer chuck. The additive manufacturing process begins by plating patterned connection level conductors and then covering the connection level conductors with a layer of dielectric material. Grinding or thinning can be performed on the dielectric material to expose portions of top surface of the layer of conductors from the dielectric material. Additional plating layers can be formed to add additional levels of trace level conductors, some of which are trace layers that are coupled to other trace layers in the dielectric materials by connection level conductors, and additional dielectric material can be deposited at each trace layer level and can cover the conductors. Example techniques of the additive manufacturing process are described in related U.S. application Ser. No. 18/327,036, filed on May 31, 2023, titled “WAFER LEVEL PROCESS FOR SEMICONDUCTOR DEVICE PACKAGE,” which is incorporated herein by its entirety.

By using the additive or build-up manufacturing approach, and by performing multiple plating steps, multiple dielectric formation steps, and multiple grinding steps, a build-up routing layer is formed directly on a semiconductor die with a number of trace level conductor layers and connection level conductor layers between and coupling portions of the trace level conductor layers. In at least one example, the use of a build-up routing layer formed in a wafer level process eliminates the need for mounting singulated semiconductor dies to a separate package substrate. The use of the build-up routing layer formed at the wafer level eliminates the die handling and die mounting steps used in prior packaging process approaches, and eliminates the use of a lead frame or other package substate between the semiconductor dies and the package terminals. Such arrangements enable thinner semiconductor device packages, and reduce the need for a wire bond or a solder joint connection between the semiconductor die and the terminals, thereby increasing performance and increasing reliability by reducing the risk of a failed connection or of a high resistance connection. In at least one example, an electrical path from the bond pad on the semiconductor die to the package terminals is formed entirely from plated conductors formed directly in contact with one another, so that the materials can be the same, and the resistance of the electrical path can be relatively low, without the use of a solder joint or bond wire.

In at least one example, the multiple conductor layers of the build-up film as first substrate 204 include copper, gold, nickel, palladium, silver, tin, or tungsten conductors that are formed by plating, and a thermoplastic material can be used as the dielectric material. Alternative materials that can be plated as conductors or as an added plating on the conductors include gold, nickel, palladium, tin, and silver. Combinations of metals and alloys of these can be used. The connection level conductors between trace level conductor layers can have a variety of shapes and sizes and can include rails and pads to couple trace layers with low resistance for power and high current signals. High current signals for power semiconductor devices can be greater than a milliampere and up to several amperes.

In at least one example, isolation circuit 108 includes a second substrate 205 with third metal interconnects 206 formed by RLF technology in a third insulation material. In at least one example, second substrate 205 includes an RLF. In at least one example, second substrate 205 comprises second ABF. In at least one example, second substrate 205 can include multiple layers of metal interconnects including third metal interconnects 206. In at least one example, second insulation material 204e is different from the third insulation material of second substrate 205. In at least one example, second insulation material 204e is same as the third insulation material of second substrate 205.

In at least one example, isolation circuit 108 comprises a transformer formed in second and third metal interconnects 204c and 206, respectively, separated by a critical separation distance tₛ based on target isolation characteristics of isolation circuit 108. The critical separation may be one or more minimum distances between second and third metal interconnects 204c and 206 (e.g., primary and secondary windings) of an isolation circuit to achieve a target voltage isolation rating (e.g., to support a certain voltage difference between the second and third metal interconnects 204c and 206 without a voltage breakdown of the isolation material between second and third metal interconnects 204c and 206). In at least one example, primary winding of transformer 108a is formed using third metal interconnects 206 while secondary winding of transformer 108a is formed using second metal interconnects 204c. Accordingly, by using different types of second insulation material 204e as isolation material, the critical separation distance tₛ between primary and secondary windings can be adjusted to meet different voltage isolation ratings.

In at least one example, second insulation material 204e has a thickness (e.g., critical separation distance tₛ) in the z-direction sufficient to provide a galvanic isolation barrier that can withstand at least 5 kilovolts (kV) root mean square (RMS) for 60 seconds in one example and at least 2.5 kV RMS for 60 seconds in another example. However, different isolation ratings may be achievable based at least in part on the type and thickness of second insulation material 204e.

In at least one example, using a mold compound, such as a compression molding film, as the material for second insulation material 204e, instead of a laminate, allows for a smaller critical separation between the first and second windings of transformer 108a while maintaining the same voltage insulation and allows for improved thermal performance of isolation circuit 108. Also, making second substrate 205 using plated traces allows for thicker copper traces (e.g., 30-35 micrometers or thicker, for instance 1%, 5%, or 10% thicker) and smaller metal width and spacing (e.g., 30×30 micrometers² or less, for instance 1%, 5%, or 10% less). This may lead to an improved efficiency of power transformer 108a by allowing an increased quality factor (QF). Integrating power and data transformers 108a and 108b into first and second substrates 204 and 205, respectively, allows for smaller packaged IC sizes (e.g., 5.0×3.0×0.8 millimeters³ or less, for instance 1%, 5%, or 10% less). In at least one example, second substrate 205 is made using etched traces. In at least one example, second substrate 205 is made using an hybrid approach with a core made of ABF and other layers made with pre-preg like laminate.

While the examples herein illustrate isolation circuit 108 as one or more transformers, isolation circuit 108 can also include capacitors. For example, one or more capacitors can be formed using second and third metal interconnects 204c and 206 between second insulation material 204e in addition to the one or more transformers or instead of the one or more transformers.

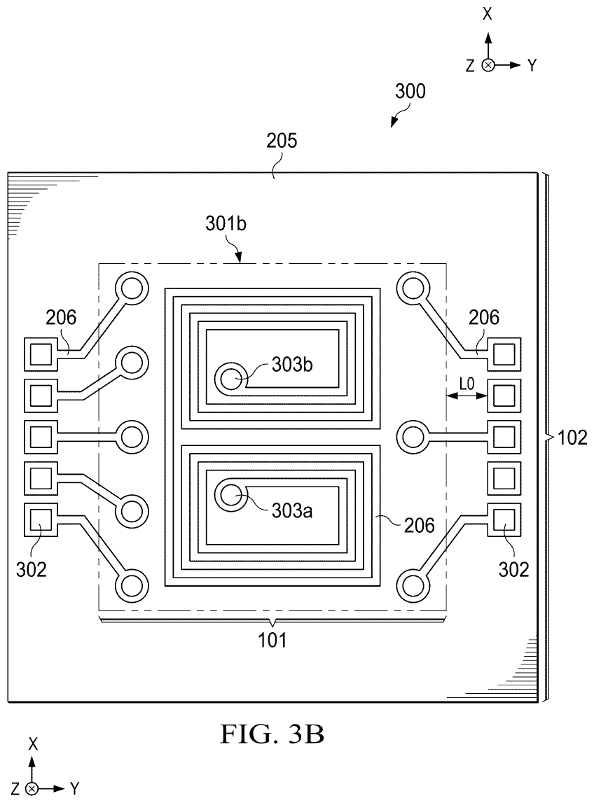

FIG. 3A is a schematic depicting a cross-sectional view of a stack of layers 300 of packaged IC 100 including first semiconductor die 101 on top of isolation circuit 108, which is on second semiconductor die 102, in accordance with at least one example. In at least one example, first semiconductor die 101 is a flip-chip die comprising a BEOL layer 301a coupled to substrate 301b. In at least one example, BEOL layer 301a is a metallization layer with metal interconnects in a substrate (e.g., silicon dioxide). In at least one example, first metal interconnects 203a, second metal interconnects 204c, and/or third metal interconnects 206 are electrically coupled to bond pads 302. In at least one example, first semiconductor die 101 is coupled to third metal interconnects 206 via metal posts or pillars 303a and 303b. In at least one example, metal posts or pillars 303a and 303b comprise one of copper, gold, nickel, palladium, silver, tin, tungsten, or a combination of them. In at least one example, bond pads 302 are placed along a periphery of second substrate 205. In at least one example, first semiconductor die 101 and second semiconductor die 102 are coupled to pins of packaged IC 100 via bond wires such as bond wires 304, which are coupled to bond pads 302, respectively. In at least one example, bond pads 302 are fully or partially embedded in second substrate 205. In at least one example, at least parts of first semiconductor die 101, metal posts/pillars 303a/303b, bond wires 304, first substrate 204, second substrate 205, and second semiconductor die 102 are covered in a molding compound.

In at least one example, first semiconductor die 101 is coupled to the primary winding of transformer 108a through metal posts or pillars 303a and/or 303b. In at least one example, metal posts or pillars 303a and/or 303b are coupled to BEOL layer 301a of first semiconductor die 101. In at least one example, transformer 108b has a first portion in a first opening of the first winding of transformer 108a and has a second portion in a second opening of the first winding of transformer 108a. In at least one example, the first portion and the second portion of transformer 108b are coupled through BEOL layer 301a and through metal posts or pillars 303a and 303b. In at least one example, the secondary winding of transformer 108a is coupled to second semiconductor die 102 through second metal interconnect 204b (e.g., a metal post or pillar) and first metal interconnects 203a in first insulation material 203 of second semiconductor die 102.

In at least one example, insulation material 204e provides further isolation between isolation circuit 108 and second semiconductor die 102 along, for example, a thickness of insulation material 204e in the z-direction. This additional isolation can improve galvanic isolation when first semiconductor die 101 operates on a different power supply than second semiconductor die 102.

FIG. 3B is a schematic depicting a top view of the schematic of FIG. 3A, in accordance with at least one example. The top view shows that first semiconductor die 101 has a smaller footprint than second semiconductor die 102. In at least one example, there is a minimum separation L0 between bond pads 302 and edge of first semiconductor die 101. The minimum separation L0 is a lateral separation in the x-direction (in this example) and is provided because the primary winding using third metal interconnects 206 in second substrate 205 may be in a different voltage domain (e.g., voltage domain of first semiconductor die 101) than a voltage domain of first metal interconnects 203a, which may be the voltage domain of second semiconductor die 102.

In at least one example, flip-chip nature of second semiconductor die 102 allows connection with the transformer(s) below it with reduced interconnection. The footprint of packaged IC 100 is defined by the footprint of second semiconductor die 102 in the stacked configuration of FIG. 3A. The stacked configuration provides a tight control on parasitics because the dies are tightly packed and interconnect distances are short.

In at least one example, metal posts or pillars 303a and 303b provide additional vertical clearance (in the z-direction) between third metal interconnects 206 and first semiconductor die 101, which can further to reduce the effect of fringing electric field between third metal interconnects 206 and first semiconductor die 101).

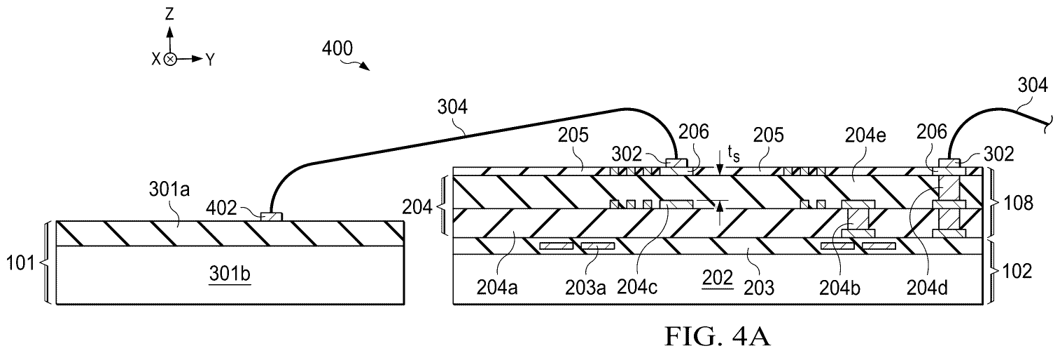

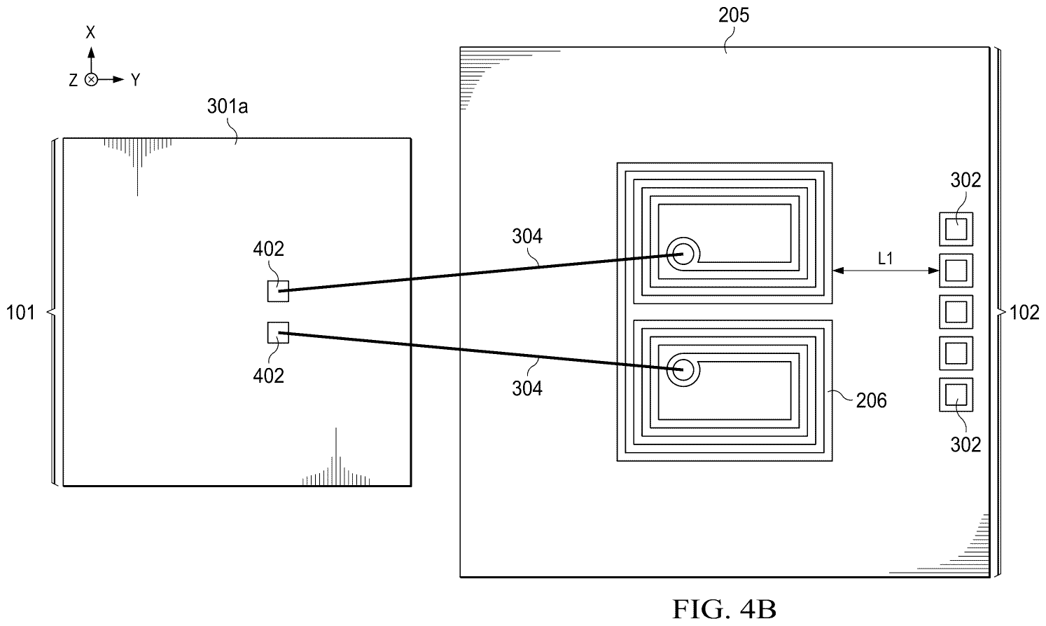

FIG. 4A is a schematic depicting a cross-sectional view of a stack of layers 400 of packaged IC 100 comprising isolation circuit 108, which is on second semiconductor die 102 and, where first semiconductor die 101 is adjacent to second semiconductor die 102, in accordance with at least one example. In at least one example, first and second semiconductor dies 101 and 102 are mounted on package substrate 110. In at least one example, bond pads 402 are formed on first semiconductor die 101 that allow coupling with isolation circuit 108 via bond wire 304. In at least one example, bond pads 402 are fully or partially embedded in BEOL layer 301a. In at least one example, at least parts of first semiconductor die 101, bond wires 304, first substrate 204, second substrate 205, and second semiconductor die 102 are covered in a molding compound.

FIG. 4B is a schematic depicting a top view of the schematic of FIG. 4A, in accordance with at least one example. In at least one example, there is minimum separation L1 between bond pads 302 and primary winding of transformer 108a in second substrate 205. The minimum separation L1 is a lateral separation in the x-direction (in this example) and is provided because the primary winding using third metal interconnects 206 in second substrate 205 may be in a different voltage domain (e.g., voltage domain of first semiconductor die 101) than a voltage domain of first metal interconnects 203a, which may be the voltage domain of second semiconductor die 102. In the examples of FIG. 4A and FIG. 4B, the footprint of second semiconductor die 102 can be larger, smaller, or the same as the footprint of first semiconductor die 101. In at least one example, die sizes or footprint of first semiconductor die 101 and second semiconductor die 102 are smaller in FIGS. 4A and 4B than in FIGS. 3A and 3B.

FIGS. 5A-C illustrate schematics of top views of stacked layers 500, 520, and 530 based on the schematic of FIG. 3A showing a single channel power isolation transformer, a single channel data isolation transformer, and multi-channel data isolation transformers, respectively, in accordance with some examples. Stacked layers 500, 520, and 530 can be examples of stacked layers 200 and 300 and can be part of packaged IC 100 of FIGS. 1A and 1B. In stacked layer 500, a figure-of-B configuration is shown for the primary winding of transformer 108a (e.g., power transformer) using third metal interconnects 206 in second substrate 205. In stacked layer, a figure-of-8 configuration is shown for the primary winding of transformer 108a using third metal interconnects 206 in second substrate 205. In at least one example, figure-of-8 configuration may include three connection taps including a first tap 523a, a center tap 523b, and a second tap 523c which, in at least one example, can be coupled to the first semiconductor die 101 via copper pillars and/or bond wires as described above. In at least one example, center tap 523b is not present. In stacked layer 530, four figure-of-8 configurations are shown for the primary windings of transformer 108b (e.g., data transformer) using third metal interconnects 206 in second substrate 205. In at least one example, windings of data transformer 108b can be implemented inside openings of the windings of power transformer 108a. While FIGS. 5B-C illustrate one winding per transformer, more than one winding or turn in a metal layer can be implemented.

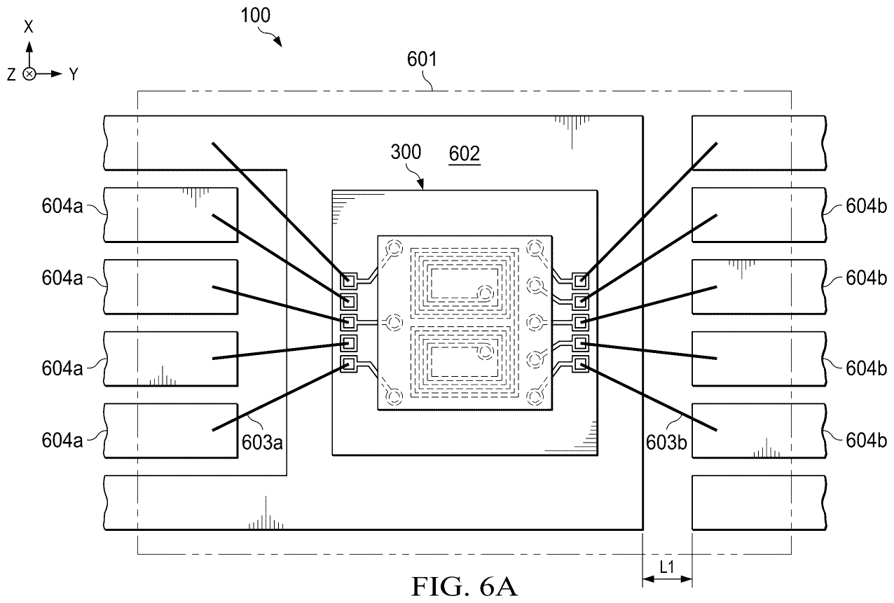

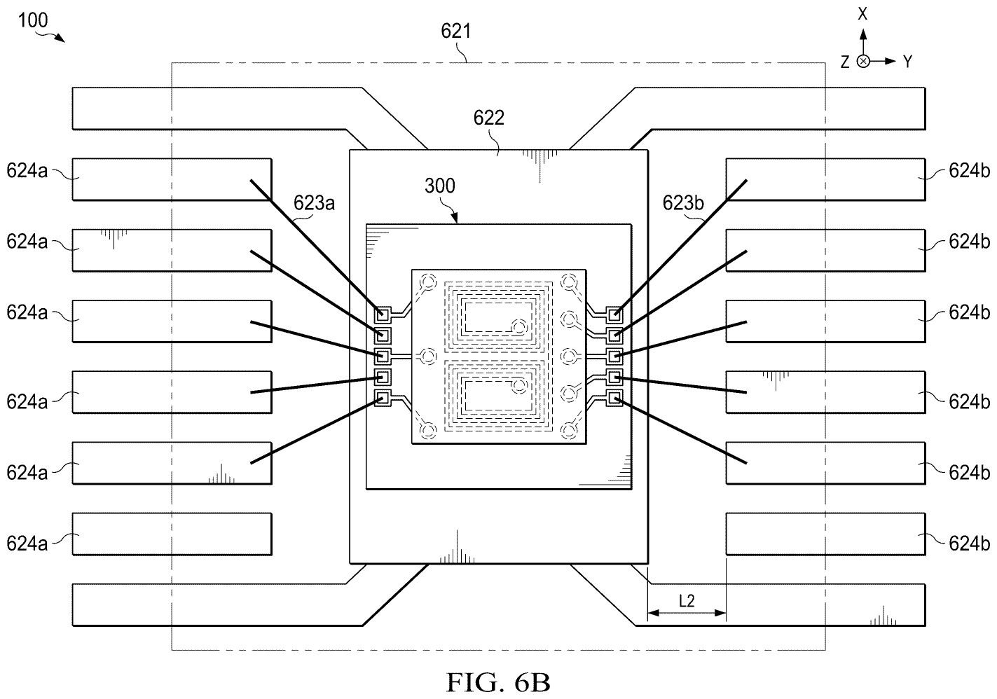

FIGS. 6A-B illustrate schematics of packaged ICs having functional isolation and reinforced isolation, respectively, in accordance with some examples. In at least one example, packaged IC 100 of FIG. 6A comprises stack of layers 300 surrounded by a mold compound within a package casing 601. In at least one example, stack of layers 300, including first semiconductor die 101, first substrate 204, second substrate 205, and second semiconductor die 102, is or forms part of a flat no-leads package, in particular a dual-flat no-leads (DFN) package. In at least one example, die attach pad 602 is connected to one or more pins. In at least one example, contact pads area of pins 604a and 604b used to mount stack of layers 300 to a package substrate are arranged such that packaged IC 100 forms a quad-flat no-leads (QFN) package. In at least one example, pins 604a and 604b of packaged IC 100 of FIG. 6A are coupled to bond pads 302 via bond wires 603a and 603b. In at least one example, a minimum distance L1 is provided between the edge of die attach pad 602 and edge of pins 604b. The minimum separation L1 is a lateral separation and is provided because the primary winding using third metal interconnects 206 in second substrate 205 may be in a different voltage domain (e.g., voltage domain of first semiconductor die 101) than a voltage domain of first metal interconnects 203a, which may be the voltage domain of second semiconductor die 102. The minimum separation L1 provides the basic or functional isolation between power domains.

In at least one example, packaged IC 100 of FIG. 6B comprises stack of layers 300 surrounded by a mold compound within a casing 621. In at least one example, contact pads area of pins 622, 624a, and 624b used to mount stack of layers 300 to a package substrate are arranged such that packaged IC 100 of FIG. 6B forms a quad-flat no-leads (QFN) package. In at least one example, pins 622, 624a, and 624b of packaged IC 100 of FIG. 6B are coupled to bond pads 302 via bond wires 623a and 623b. In at least one example, casing 621 is larger than casing 601 because minimum distance L2 between the edge of first semiconductor die 101 and edge of the closest pins 624 may be greater than minimum distance L1. The minimum separation L2 provides the higher or reinforced isolation between power domains because the minimum separation L2 is greater than minimum separation L1.

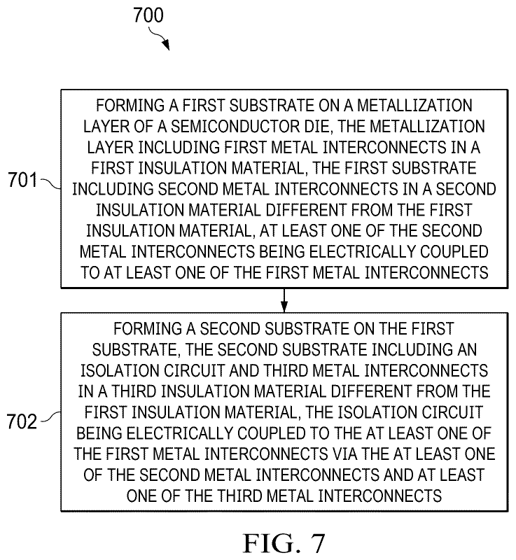

FIG. 7 is a flowchart 700 of a method of forming the packaged IC, in accordance with at least one example. Part of flowchart 700 may be performed by wafer-level QFN build-up process and part of flowchart 700 may be performed by an RLF process.

At block 701, first substrate 204 is formed on a first insulation material 203 (e.g., silicon material), which includes a metallization layer. The first insulation material 203 is part of second semiconductor die 102. In at least one example, the metallization layer includes first metal interconnects 203a in first insulation material 203 (e.g., silicon dioxide). In at least one example, the process of forming first substrate 204, which includes a wafer-level build-up QFN film that enables lamination of dielectric on top of a wafer is described in U.S. patent application Ser. No. 18/327,036.

In at least one example, second semiconductor die 102 is one of many dies on a semiconductor wafer and includes bond pads on a device side surface and an opposing backside surface. In at least one example, the method comprises forming a build-up routing layer over the semiconductor wafer. In at least one example, forming the build-up routing layer includes patterning connection level conductors over the device side surface of the semiconductor dies (including second semiconductor die 102) to form post connects contacting bond pads of the semiconductor dies and extending to a distal end. In at least one example, forming the build-up routing layer includes forming a first layer of dielectric material over and surrounding the post connects. In at least one example, forming the build-up routing layer further includes grinding the first layer of dielectric material (e.g., first insulation material 204a) to expose the distal ends of the post connects, and patterning trace level conductors over the first layer of dielectric material. The trace level conductors contact distal ends of the post connects. In at least one example, the method comprises depositing a second layer of dielectric material (e.g., second insulation material 204e) over the connection level conductors (e.g., second metal interconnect 204c) and the trace level conductors (e.g., posts of second metal interconnect 204d). The method further comprises grinding the second dielectric layer to expose a surface of the trace level conductors, portions of the exposed surface of the trace level conductors forming terminals for semiconductor device packages.

In at least one example, the method continues by cutting through the build-up routing layer in scribe lanes between the semiconductor dies to form trenches extending into the semiconductor wafer. Scribe lanes may be arranged on four sides of semiconductor dies and when the dies are singulated from one another, rectangular semiconductor dies are formed.

In at least one example, the method comprises backgrinding the semiconductor wafer on the backside surface of the semiconductor wafer to form openings by exposing the trenches to separate the semiconductor dies from one another. In at least one example, the method comprises covering the device side surface of the semiconductor dies, a portion of the routing layers, the openings between the semiconductor dies, and the board side surface of the semiconductor dies with mold compound, while the terminals formed of the trace level conductors are exposed from the mold compound.

In at least one example, first substrate 204 includes second metal interconnects 204b, 204c, and 204d in second insulation material 204e different from first insulation material 203. In at least one example, at least one of second metal interconnects 204b, 204c, and 204d is electrically coupled to at least one of first metal interconnects 203a. In at least one example, forming first substrate 204 includes forming second metal interconnects 204b, 204c, and 204d by plating. In at least one example, forming first substrate 204 further includes forming second insulation material 204e around at least some of second metal interconnects such as second metal interconnects 204b and 204d. In at least one example, forming first substrate 204 further includes molding and backgrinding second insulation material 204e.

At block 702, second substrate 205 (e.g., an RLF) is formed on first substrate 204. In at least one example, second substrate 205 includes isolation circuit 108 and third metal interconnects 206 in a third insulation material (e.g., ABF) different from first insulation material 203. In at least one example, isolation circuit 108 is electrically coupled to at least one of the first metal interconnects 203a via at least one of the second metal interconnects 204b, 204c, and 204d and at least one of third metal interconnects 206.

In at least one example, forming second substrate 205 includes forming third metal interconnects 206 by plating. In at least one example, forming second substrate includes 205 forming the third insulation material around at least some of third metal interconnects 206. In at least one example, polyimide is applied with a coating step and then exposed to light where it must stay. Unexposed areas are developed away to create the opening. The same process can be applied to make solder mask.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementation without changing the scope of disclosure.

Example 1 is a packaged integrated circuit comprising: a semiconductor die having a metallization layer, the metallization layer including first metal interconnects in a first insulation material; a first substrate on the metallization layer, the first substrate including second metal interconnects in a second insulation material different from the first insulation material, at least one of the second metal interconnects being electrically coupled to at least one of the first metal interconnects; and a second substrate on the first substrate, the second substrate including an isolation circuit and third metal interconnects in a third insulation material different from the first insulation material, the isolation circuit being electrically coupled to the at least one of the first metal interconnects via the at least one of the second metal interconnects and at least one of the third metal interconnects.

Example 2 is a packaged integrated circuit according to any example, in particular example 1, wherein the first insulation material includes silicon dioxide.

Example 3 is a packaged integrated circuit according to any example, in particular example 1, wherein the second and third insulation materials include at least one of: a build-up film, a solder mask, or an epoxy material (polyimide).

Example 4 is a packaged integrated circuit according to any example, in particular example 3, wherein the second and third insulation materials include a same insulation material.

Example 5 is a packaged integrated circuit according to any example, in particular example 1, wherein the second substrate includes a routable lead frame (RLF).

Example 6 is a packaged integrated circuit according to any example, in particular example 1, wherein the second metal interconnects include one or more metal posts.

Example 7 is a packaged integrated circuit according to any example, in particular example 1, further comprising: bond pads on a periphery of the semiconductor die and the first and second substrates; and bond wires coupled between the bond pads and at least some of the third metal interconnects.

Example 8 is a packaged integrated circuit according to any example, in particular example 1, wherein the semiconductor die is a first semiconductor die, the metallization layer is a first metallization layer, the at least one of the third metal interconnects include a first one of the third metal interconnects, and the package integrated circuit further comprises a second semiconductor die having a second metallization layer, the second metallization layer including fourth metal interconnects in a fourth insulation material, and at least one of the fourth metal interconnects being electrically coupled to a second one of the third metal interconnects.

Example 9 is a packaged integrated circuit according to any example, in particular example 8, wherein the second semiconductor die is on the second substrate, and the packaged integrated circuit further comprises metal posts coupled between the second semiconductor die and the second substrate, the at least one of the fourth metal interconnects being electrically coupled to the second one of the third metal interconnects via one of the metal posts.

Example 10 is a packaged integrated circuit according to any example, in particular example 8, wherein the second semiconductor die is adjacent to the first semiconductor die and the first and second substrates, and the packaged integrated circuit further comprises bond wires coupled between the second semiconductor die and the second substrate, the at least one of the fourth metal interconnects being electrically coupled to the second one of the third metal interconnects via one of the bond wires.

Example 11 is a packaged integrated circuit according to any example, in particular example 1, wherein the isolation circuit includes one or more transformers.

Example 12 is a packaged integrated circuit according to any example, in particular example 1, wherein the isolation circuit is configured to provide at least one of power isolation or data isolation between the first semiconductor die and the second semiconductor die.

Example 13 is a packaged integrated circuit including: a semiconductor die having a metallization layer, the metallization layer including first metal interconnects in a dielectric material; a first layer on the metallization layer, the first layer including second metal interconnects in a first build-up material, at least some of the second metal interconnects electrically coupled to at least some of the first metal interconnects; and a second layer on the first layer, the second layer including third metal interconnects in a second build-up material, at least a first subset of the third metal interconnects electrically coupled to the at least some of the second metal interconnects, and at least a second subset of the third metal interconnects are exposed by the second layer.

Example 14 is a packaged integrated circuit according to any example, in particular example 13, wherein the second layer includes an isolation circuit electrically coupled to at least some of the first subset of the third metal interconnects.

Example 15 is a packaged integrated circuit according to any example, in particular example 13, wherein the semiconductor die is a first semiconductor die, the metallization layer is a first metallization layer, and the package integrated circuit further comprises a second semiconductor die having a second metallization layer, the second metallization layer including fourth metal interconnects in a fourth insulation material, and at least one of the fourth metal interconnects being electrically coupled to at least some of the second subset of the third metal interconnects.

Example 16 is a packaged integrated circuit according to any example, in particular example 15, wherein the second semiconductor die is on the second layer, and the packaged integrated circuit further comprises metal posts coupled between the second semiconductor die and the second layer, the at least one of the fourth metal interconnects being electrically coupled to the second one of the third metal interconnects via one of the metal posts.

Example 17 is a packaged integrated circuit according to any example, in particular example 15, wherein the second semiconductor die is adjacent to the first semiconductor die and the first and second layers, and the packaged integrated circuit further comprises bond wires coupled between the second semiconductor die and the second layer, the at least one of the fourth metal interconnects being electrically coupled to the second one of the third metal interconnects via one of the bond wires.

Example 18 is a packaged integrated circuit according to any example, in particular example 13, wherein the second layer includes a routable lead frame (RLF).

Example 19 is a packaged integrated circuit according to any example, in particular example 13, wherein the second metal interconnects include one or more metal posts.

Example 20 is a method comprising: forming a first substrate on a metallization layer of a semiconductor die, the metallization layer including first metal interconnects in a first insulation material, the first substrate including second metal interconnects in a second insulation material different from the first insulation material, at least one of the second metal interconnects being electrically coupled to at least one of the first metal interconnects; and forming a second substrate on the first substrate, the second substrate including an isolation circuit and third metal interconnects in a third insulation material different from the first insulation material, the isolation circuit being electrically coupled to the at least one of the first metal interconnects via the at least one of the second metal interconnects and at least one of the third metal interconnects.

Example 21 is a method according to any example, in particular example 20, wherein forming the first substrate includes: forming the second metal interconnects by plating; forming the second insulation material around at least some of the second metal interconnects; molding and backgrinding the second insulation material.

Example 22 is a method according to any example, in particular example 20, wherein forming the second substrate includes: forming the third metal interconnects by plating; and forming the third insulation material around at least some of the third metal interconnects.

Example 23 is a method according to any example, in particular example 20, wherein the semiconductor die is a first semiconductor die, the metallization layer is a first metallization layer, the at least one of the third metal interconnects include a first one of the third metal interconnects, and the method further comprises: electrically coupling a fourth metal interconnect to a second one of the third interconnects, wherein the fourth metal interconnect is in a fourth insulation material of the second metallization layer of a second semiconductor die.

Example 24 is a method according to any example, in particular example 23, further comprising: placing the second semiconductor die on the second substrate; coupling metal posts between the second semiconductor die and the second substrate, the at least one of the fourth metal interconnects being electrically coupled to the second one of the third metal interconnects via one of the metal posts.

Example 25 is a method according to any example, in particular example 23, further comprising: placing the second semiconductor die adjacent to the first semiconductor die and the first and second substrates; coupling bond wires between the second semiconductor die and the second substrate, the at least one of the fourth metal interconnects being electrically coupled to the second one of the third metal interconnects via one of the bond wires.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having,” and variants thereof are intended to be inclusive in a manner similar to the term “comprising” unless otherwise noted. In addition, the terms “couple,” “coupled,” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. A packaged integrated circuit including:
a semiconductor die having a metallization layer, the metallization layer including first metal interconnects in a first insulation material;
a first substrate on the metallization layer, the first substrate including second metal interconnects in a second insulation material different from the first insulation material, at least one of the second metal interconnects being electrically coupled to at least one of the first metal interconnects; and
a second substrate on the first substrate, the second substrate including an isolation circuit and third metal interconnects in a third insulation material different from the first insulation material, the isolation circuit being electrically coupled to the at least one of the first metal interconnects via the at least one of the second metal interconnects and at least one of the third metal interconnects.

2. The packaged integrated circuit of claim 1, wherein the first insulation material includes silicon dioxide.

3. The packaged integrated circuit of claim 1, wherein the second and third insulation materials include at least one of: a build-up film, a solder mask, or an epoxy material (polyimide).

4. The packaged integrated circuit of claim 3, wherein the second and third insulation materials includes a same insulation material.

5. The packaged integrated circuit of claim 1, wherein the second substrate includes a routable lead frame (RLF).

6. The packaged integrated circuit of claim 1, wherein the second metal interconnects include one or more metal posts.

7. The packaged integrated circuit of claim 1, further comprising:
bond pads on a periphery of the semiconductor die and the first and second substrates; and
bond wires coupled between the bond pads and at least some of the third metal interconnects.

8. The packaged integrated circuit of claim 1, wherein the semiconductor die is a first semiconductor die, the metallization layer is a first metallization layer, the at least one of the third metal interconnects include a first one of the third metal interconnects, and the package integrated circuit further comprises a second semiconductor die having a second metallization layer, the second metallization layer including fourth metal interconnects in a fourth insulation material, and at least one of the fourth metal interconnects being electrically coupled to a second one of the third metal interconnects.

9. The packaged integrated circuit of claim 8, wherein the second semiconductor die is on the second substrate, and the packaged integrated circuit further comprises metal posts coupled between the second semiconductor die and the second substrate, the at least one of the fourth metal interconnects being electrically coupled to the second one of the third metal interconnects via one of the metal posts.

10. The packaged integrated circuit of claim 8, wherein the second semiconductor die is adjacent to the first semiconductor die and the first and second substrates, and the packaged integrated circuit further comprises bond wires coupled between the second semiconductor die and the second substrate, the at least one of the fourth metal interconnects being electrically coupled to the second one of the third metal interconnects via one of the bond wires.

11. The packaged integrated circuit of claim 1, wherein the isolation circuit includes one or more transformers.

12. The packaged integrated circuit of claim 1, wherein the isolation circuit is configured to provide at least one of power isolation or data isolation between the first semiconductor die and the second semiconductor die.

13. A packaged integrated circuit including:
a semiconductor die having a metallization layer, the metallization layer including first metal interconnects in a dielectric material;
a first layer on the metallization layer, the first layer including second metal interconnects in a first build-up material, at least some of the second metal interconnects electrically coupled to at least some of the first metal interconnects; and
a second layer on the first layer, the second layer including third metal interconnects in a second build-up material, at least a first subset of the third metal interconnects electrically coupled to the at least some of the second metal interconnects, and at least a second subset of the third metal interconnects are exposed by the second layer.

14. The packaged integrated circuit of claim 13, wherein the second layer includes an isolation circuit electrically coupled to at least some of the first subset of the third metal interconnects.

15. The packaged integrated circuit of claim 13, wherein the semiconductor die is a first semiconductor die, the metallization layer is a first metallization layer, and the package integrated circuit further comprises a second semiconductor die having a second metallization layer, the second metallization layer including fourth metal interconnects in a fourth insulation material, and at least one of the fourth metal interconnects being electrically coupled to at least some of the second subset of the third metal interconnects.

16. The packaged integrated circuit of claim 15, wherein the second semiconductor die is on the second layer, and the packaged integrated circuit further comprises metal posts coupled between the second semiconductor die and the second layer, the at least one of the fourth metal interconnects being electrically coupled to the second one of the third metal interconnects via one of the metal posts.

17. The packaged integrated circuit of claim 15, wherein the second semiconductor die is adjacent to the first semiconductor die and the first and second layers, and the packaged integrated circuit further comprises bond wires coupled between the second semiconductor die and the second layer, the at least one of the fourth metal interconnects being electrically coupled to the second one of the third metal interconnects via one of the bond wires.

18. The packaged integrated circuit of claim 13, wherein the second layer includes a routable lead frame (RLF).

19. The packaged integrated circuit of claim 13, wherein the second metal interconnects include one or more metal posts.

20. A method comprising:
forming a first substrate on a metallization layer of a semiconductor die, the metallization layer including first metal interconnects in a first insulation material, the first substrate including second metal interconnects in a second insulation material different from the first insulation material, at least one of the second metal interconnects being electrically coupled to at least one of the first metal interconnects; and
forming a second substrate on the first substrate, the second substrate including an isolation circuit and third metal interconnects in a third insulation material different from the first insulation material, the isolation circuit being electrically coupled to the at least one of the first metal interconnects via the at least one of the second metal interconnects and at least one of the third metal interconnects.

21. The method of claim 20, wherein forming the first substrate includes:
forming the second metal interconnects by plating;
forming the second insulation material around at least some of the second metal interconnects;
molding and backgrinding the second insulation material.

22. The method of claim 20, wherein forming the second substrate includes:
forming the third metal interconnects by plating; and
forming the third insulation material around at least some of the third metal interconnects.

23. The method of claim 20, wherein the semiconductor die is a first semiconductor die, the metallization layer is a first metallization layer, the at least one of the third metal interconnects include a first one of the third metal interconnects, and the method further comprises:
electrically coupling a fourth metal interconnect to a second one of the third interconnects, wherein the fourth metal interconnect is in a fourth insulation material of the second metallization layer of a second semiconductor die.

24. The method of claim 23, further comprising:
placing the second semiconductor die on the second substrate;
coupling metal posts between the second semiconductor die and the second substrate, the at least one of the fourth metal interconnects being electrically coupled to the second one of the third metal interconnects via one of the metal posts.

25. The method of claim 23, further comprising:
placing the second semiconductor die adjacent to the first semiconductor die and the first and second substrates;
coupling bond wires between the second semiconductor die and the second substrate, the at least one of the fourth metal interconnects being electrically coupled to the second one of the third metal interconnects via one of the bond wires.
